(19) United States
(12) Patent Application Publication
(10) Pub. No.: US 2024/0260233 A1
(43) Pub. Date: Aug. 1, 2024

(54) DIMM COOLING ASSEMBLIES

(71) Applicant: Intel Corporation, Santa Clara, CA (US)

(72) Inventors: Ming Zhang, Shanghai (CN); Yuehong Fan, Shanghai (CN); Peng Wei, Shanghai (CN); Chuanlou Wang, Shanghai (CN); Rajiv K. Mongia, Portland, OR (US); Guocheng Zhang, Shanghai (CN); Yingqiong Bu, Shanghai (CN); Berhanu Wondimu, Beaverton, OR (US); Guixiang Tan, Portland, OR (US); Xiang Que, Suzhou (CN); Qing Jiang, Shanghai (CN); Liu Yu, Shanghai (CN); Wei-Ming Chu, New Taipei City (TW); Chen Zhang, Shanghai (CN); Hao Zhou, Shanghai (CN); Feng Qi, Shanghai (CN); Catharina Biber, Bend, OR (US); Devdatta Prakash Kulkarni, Portland, OR (US); Xiang Li, Portland, OR (US); Yechi Zhang, Shanghai (CN)

(21) Appl. No.: 18/565,880

(22) PCT Filed: Nov. 11, 2021
(86) PCT No.: PCT/CN2021/130052

§ 371 Date: Nov. 30, 2023

Related U.S. Application Data
(60) Provisional application No. 63/233,551, filed on Aug. 16, 2021.

(51) Int. Cl. H05K 7/20; G06F 1/20; H01L 23/40; H01L 23/427; H01L 23/473

(52) U.S. Cl. CPC H05K 7/20336; G06F 1/20; H01L 23/4093; H01L 23/427; H01L 23/473; G06F 2200/201

(57) ABSTRACT

Heat pipes and vapor chambers that are components of a DIMM cooling assembly are described.

### CLAIM OF PRIORITY

This application claims the benefit of priority of U.S. Provisional Application No. 63/233,551 filed Aug. 16, 2021, entitled “LIQUID COOLED DIMM SYSTEM WITH RAPIDLY CONNECTIBLE/DISCONNECTIBLE COLD PLATE” that is hereby incorporated by reference in its entirety.

### BACKGROUND

System design engineers face challenges, especially with respect to high performance data center computing, as both computers and networks continue to pack higher and higher levels of performance into smaller and smaller packages. Creative packaging solutions are therefore being designed to keep pace with the thermal requirements of such aggressively designed systems.

### FIGURES

A better understanding of the present invention can be obtained from the following detailed description in conjunction with the following drawings, in which:

FIGS. 1a, 1b, 1c, 1d, 1e and 1f pertain to a first DIMM cooling approach;

FIGS. 2a (prior art), 2b (prior art), 2c and 2d pertain to a second DIMM cooling approach;

FIGS. 3a, 3b, 3c and 3d pertain to a second DIMM cooling approach;

FIGS. 4a, 4b, 4c, 4d and 4e pertain to a third DIMM cooling approach;

FIGS. 5a, 5b, 5c and 5d pertain to a fourth DIMM cooling approach;

FIGS. 6a, 6b, 6c, 6d, 6e, 6f, 6g and 6h pertain to a fifth DIMM cooling approach;

FIG. 7 depicts a cooling apparatus

FIG. 8 depicts a system;

FIG. 9 depicts a data center;

FIG. 10 depicts a rack.

### DETAILED DESCRIPTION

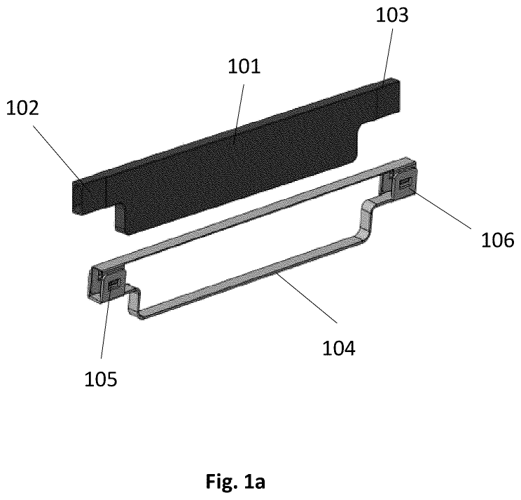

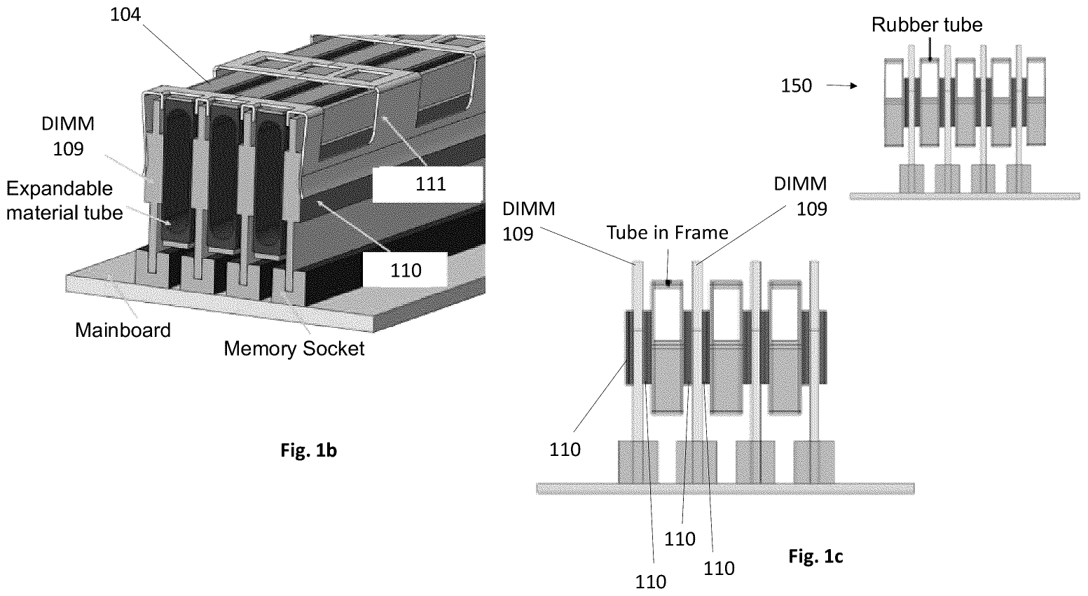

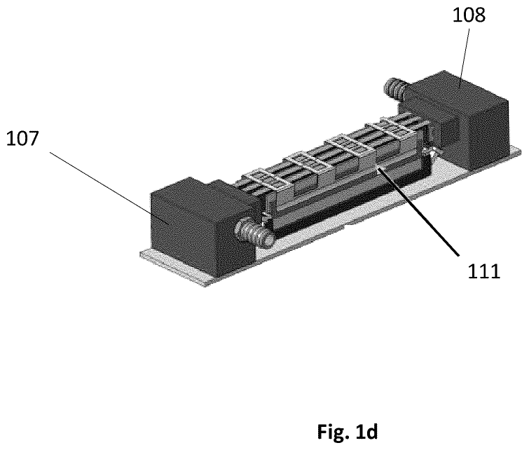

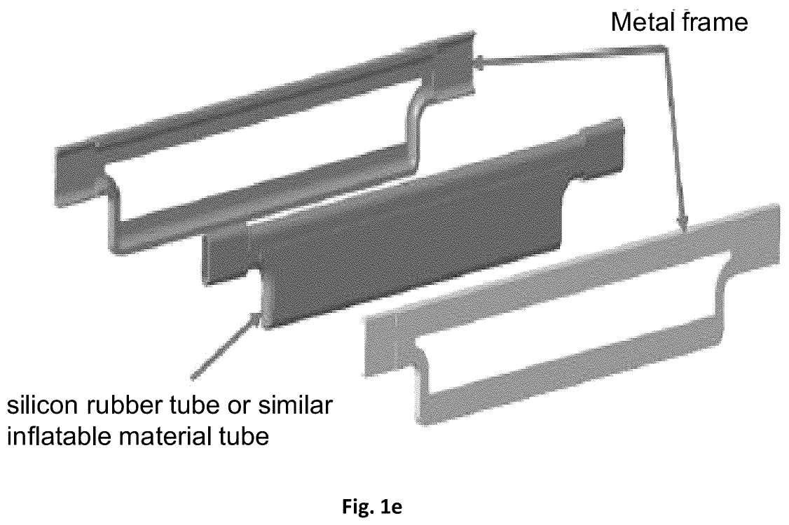

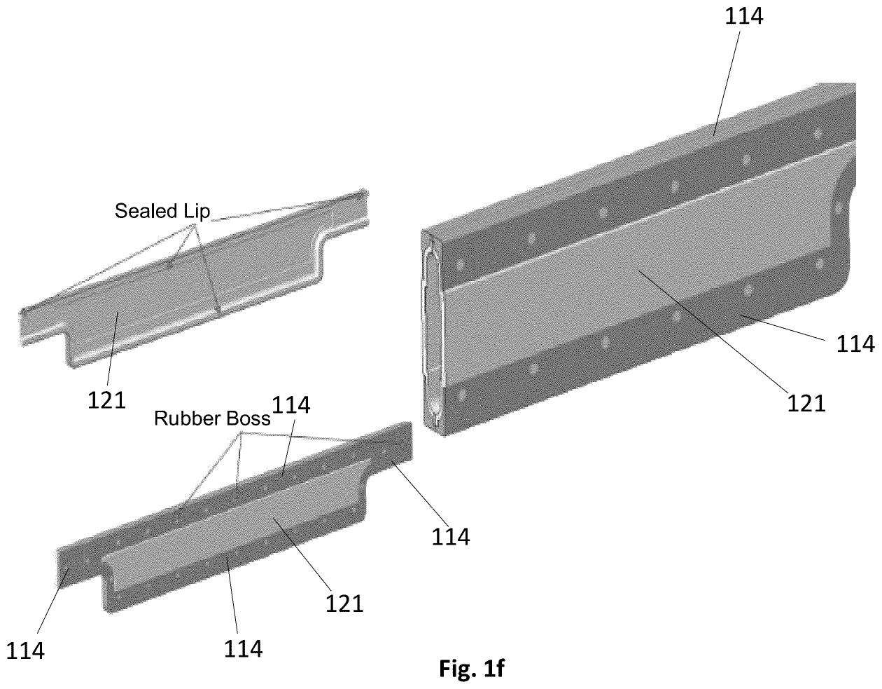

FIGS. 1a, 1b, 1c and 1d depict a first embodiment of a DIMM cooling assembly that includes a hollow, rectangular shaped, elastic tube 101. As will be described in more detail further below, the elasticity of the tube 101 allows the tube to “inflate” when cooled liquid flows through the tube 101. As such, the tube 101 is composed of elastic material such as rubber. The tube 101 also includes an inlet port 102 and an exit port 103. Coolant flows into the inlet port 102 and is warmed from heat dissipated by semiconductor chips that the tube 101 is in thermal contact with (here, thermal contact means actual contact, or, a thermal resistance that is less than or equal to that achieved with actual contact (such as that achieved with thermal paste or other thermal interface material (TIM) between the tube and chips). The warmed fluid then exits the tube from the exit port 103.

Before being plugged into the system, the elastic tube 101 is inserted into a frame 104. The frame 104 is composed of hard material (e.g., metal, plastic, ceramic, etc.), is shaped to run around the peripheral edges of the tube 101, and has open windows so that both faces of the tube 101 are exposed. The far edges of the frame 105, 106 are shaped to hold the tube's inlet port 102 and outlet port 103 and mechanically mate with a cooled fluid manifold 107 that runs along one end of a bank of DIMM sockets and a warmed fluid manifold 108 that runs along the opposite end of the bank of DIMM sockets.

The framed tube is then plugged into the manifolds 107, 108 such that the tube inlet 102 is fluidically coupled with an exit port of the cooled fluid manifold 107, the tube outlet 103 is fluidically coupled with an input port of the warmed fluid manifold 108. The frame 104 is held rigidly in place by the mechanical connection between the frame edges and both manifolds. In various embodiments, the manifold ports that are fluidly coupled to the tube ports 102, 103 (and/or the entirety of either or both manifolds 107, 108) have valves that are closed while the framed tube is being installed such that cooled fluid does not enter or exit the framed tube during its installation.

Notably, the framed tube's connection with the manifolds 107, 108 aligns the framed tube such that it resides between neighboring DIMM sockets. During the installation process, as described above, fluid is prevented from flowing through the tube 101. As such, the tube 101 is relaxed and largely (if not entirely) stays within the confines of the frame 104.

In this state, the framed tube is easily inserted between the two DIMM sockets even if DIMMs 109 occupy the slots. That is, in the relaxed state, the framed tube is easily inserted in the space that exists between neighboring DIMMs 109.

After the framed tube has been installed, the aforementioned valves are opening which permits fluid to run through the tube 101. The flowing of fluid through the tube causes the tube 101 to expand through the open windows such that faces of the tube 101 press upon the lids of the semiconductors chips 110 that are disposed on the faces of the DIMMs that face the tube. Notably, expansion of the tube 101 along its peripheral edges is blocked by the frame 104, which, in turn, promotes further expansion of the tube 101 through the frame windows and against the DIMMs' semiconductor chips 110.

The firm pressing of the expanded tube 101 against the DIMMs' semiconductor chips 110 lowers the thermal resistance between the chips 110 and the tube 101. As such, the tube 101 absorbs heat from the chips 110, which, in turn, warms the fluid as it runs through the tube 101. The warmed fluid exits the tube via the tube's exit port 103, flows into the warmed fluid manifold 108 and enters a cooling apparatus of some kind (e.g., radiator, etc.) that the warmed fluid manifold 108 is fluidically coupled to. The warmed fluid that exits the tube1 101 is replenished with cooled fluid that continually enters the tube 101 from the cooled fluid manifold 107. The cooled fluid can be supplied by the cooling apparatus that receives the warmed fluid.

FIGS. 1b and 1c show three framed tubes inserted between the spaces of four neighboring DIMMs 109. Here, an external clip 111 is used to compress the four DIMMS 109 and three tubes in a manner that further improves thermal efficiency between the DIMMs' respective semiconductor chips 110 and the framed tubes that they are respectively in contact with. In the particular embodiment of FIGS. 1b and 1c, the outer faces of the outer DIMMs are not coupled to any tube. However, in a further embodiment, as depicted at inset 150, first and second framed tubes are installed at the outer faces of the outer DIMMs so that every DIMM face is in thermal contact with a framed tube.

In various embodiments, as depicted in FIG. 1a, the tube 101 and frame 104 are separate pieces and the user inserts the tube 101 into the frame 104 prior to installation. In another embodiment, the tube 101 and frame 104 are manufactured and shipped to users as a single piece (e.g., the tube 101 is glued inside the frame 104 as part of the manufacturing process of the combined unit prior to shipment to users).

With respect to construction of the frame 104, according to one embodiment, the frame 104 is constructed as a single piece and the tube is fit into the structure of the single frame piece. In another embodiment, depicted in FIG. 1e, two separate lengthwise frame halves are constructed and then mated together along the (longer) lengthwise axis.

FIG. 1f shows another embodiment in which elastic and frame parts are integrated together as part of a single manufacturing process. Here, two halves are made where each half includes both a hard frame component 114 and an elastic component 121. The elastic component 121 is formed as an inner layer of the hard component 114 (e.g., injecting molding is used to first form the hard component and then form the elastic layer on the inside of the hard component). The elastic component 114 covers the window opening in the hard part 121. The two halves are then sealed together.

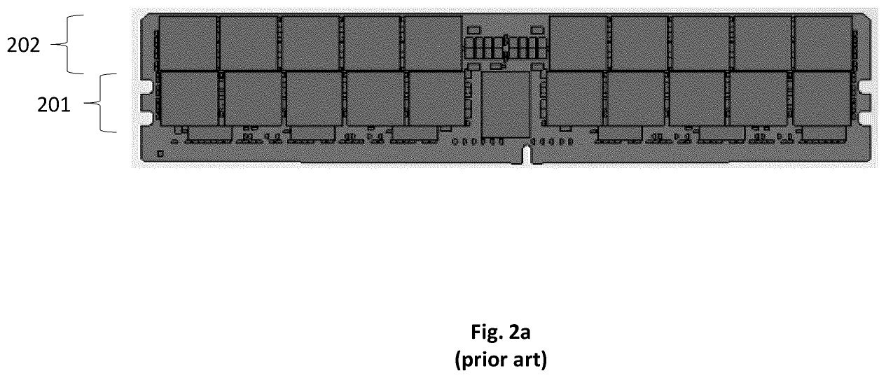

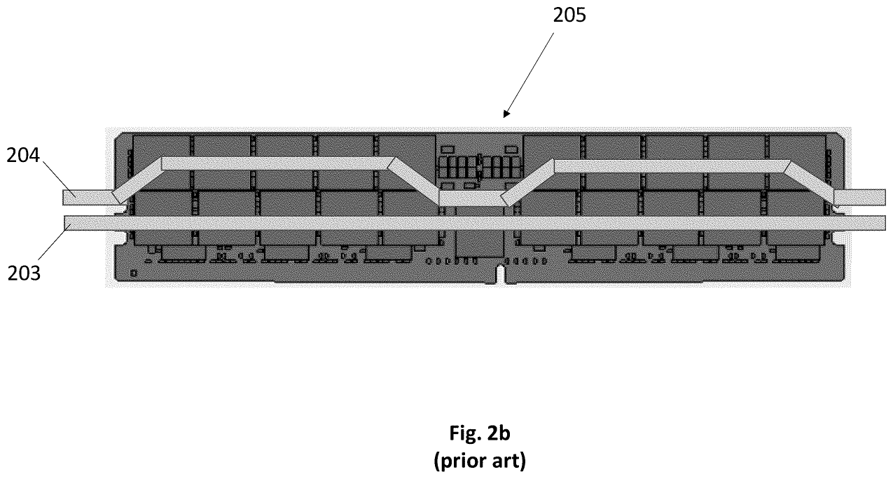

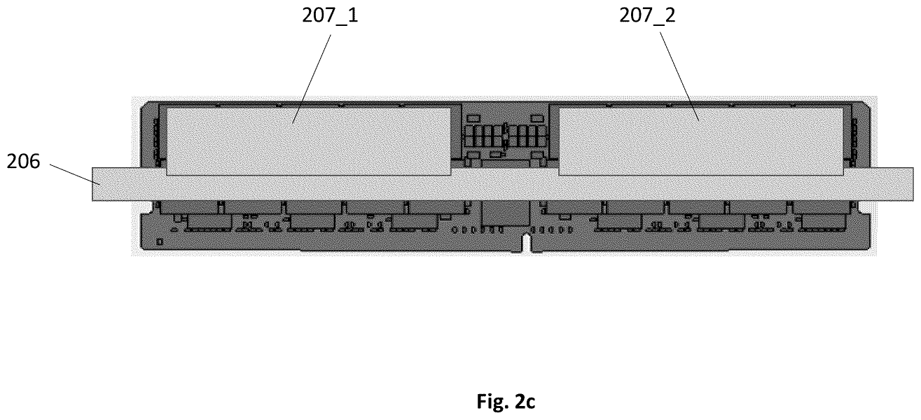

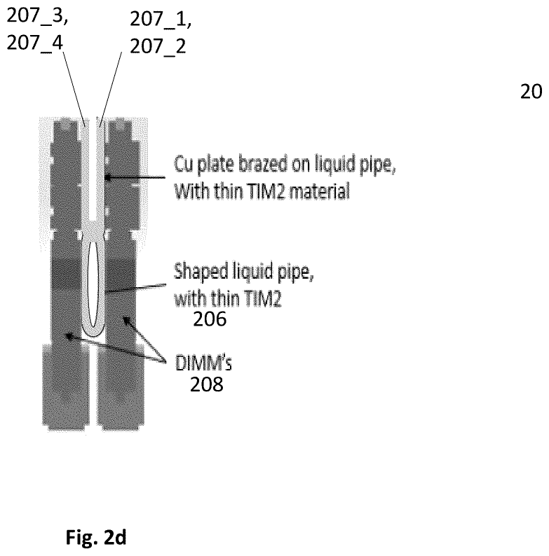

FIGS. 2a,b,c through 3a,b,c,d pertain to another embodiment that accounts for the different chip layout structures that exist on the different portions of a same DIMM face. Here, FIG. 2a depicts a face of a DIMM. As observed, the device layouts between (lower) portion 201 and (upper) portion 202 are different. The layout differences between the two portions make it difficult to cool both portions with identical cooling structures.

Specifically, FIG. 2b shows a prior art design in which a pair of heat pipes 203, 204 are used to respectively cool the different portions. Specifically, a first heat pipe 203 runs along the lids of the chips in lower portion 201. A second heat pipe 204 runs along the lids of the chips in upper portion 202. Unfortunately, there is a “gap” 205 in upper portion 202 in which, e.g., the presence of passive devices (e.g., capacitors, resistors, etc.) is more prevalent than packaged semiconductor chips (such as a memory chips, buffer chips, registering clock driver (RCD) chip, etc.).

The gap 205 corresponds to an uneven surface topography across upper portion 202, which, in turn, complicates the design of the heat pipe 204 that runs across upper portion 202. Specifically, as observed in FIG. 2b, the heat pipe 204 is routed closer to portion 201 so that it does not expand across the gap. Routing the heat pipe 204 in this manner gives the heat pipe 204 better mechanical support (it does not have to cross gap 205 where it can be bent/damaged) but, in turn, increases the fluidic resistance of the pipe 204 such that there are two significantly different rates of fluid flow between the two pipes 201, 202. Additionally, the prior art approach of FIG. 2b only attempts to run the heat pipes over one face of the DIMM and not the opposite face (there are no heat pipes on the DIMM face that is opposite the observed DIMM face of FIG. 2b).

FIG. 2c shows an improved design in which there exists one heat pipe 206 that runs along the lower portion 201 and makes thermal contact with the chips in the lower portion 201. Additionally, a pair of thermally conductive plates 207_1, 207_2 extend from the heat pipe 206 and make thermal contact with the packaged semiconductor chips in the upper portion 202.

In operation, fluid runs through the heat pipe through its being coupled to a set of manifolds as described above in the preceding embodiment of FIGS. 1a through 1f. Heat from the chips in lower portion 201 is absorbed by the fluid directly through the pipe 206. By contrast, heat from the chips in upper portion 202 is absorbed by the thermally conductive plates 207_1, 207_2 and then transferred to the fluid through the pipe 206. Although there can be thermal cooling capacity differences between the two portions 201, 202 because of their different respective thermal cooling designs, so long as the fluid flow through the heat pipe 206 is large enough to absorb sufficient amounts of heat from both portions, overall cooling will be acceptable.

Importantly, as observed in side view FIG. 2d, the pipe can have a second set of thermally conductive plates mounted to it so that it can be placed in between two neighboring DIMMs 208 and cool the chips on their respective, facing sides. That is, the heat pipe 206 is in thermal contact with the chips of the lower portions of both DIMMs 208. A first set of thermally conductive plates 207_1, 207_2 are in thermal contact with the chips of the upper portion of one of the DIMMs 208 and a second set of thermally conductive plates 207_3, 207_4 are in thermal contact with the chips of the upper portion of the other of the DIMMs 208. As such, heat from the chips of all four portions combined of the pair of DIMMs 208 are transmitted into the fluid that runs through the heat pipe 206.

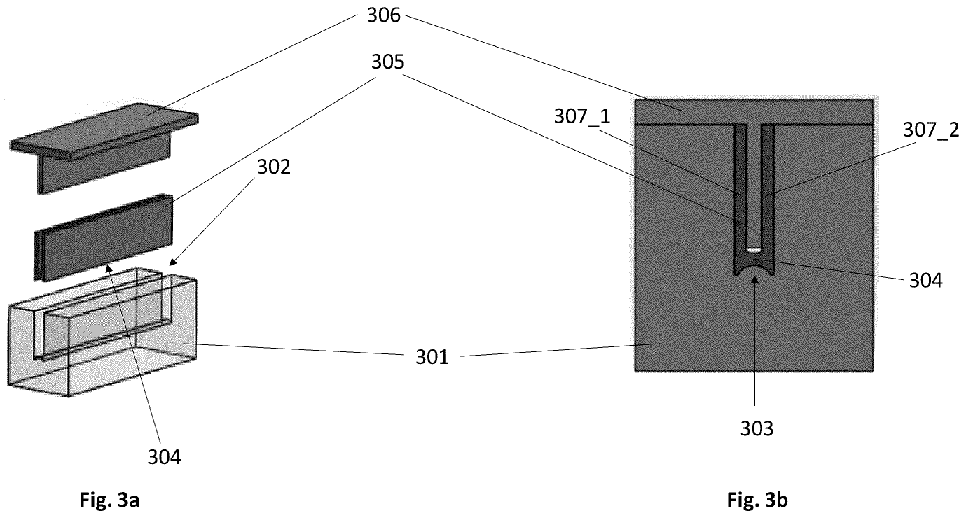

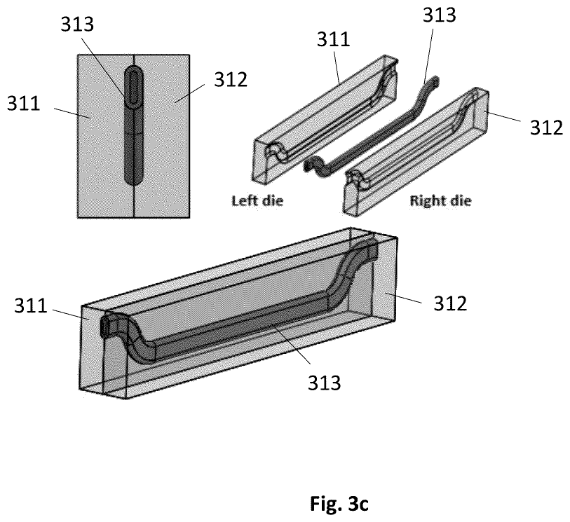

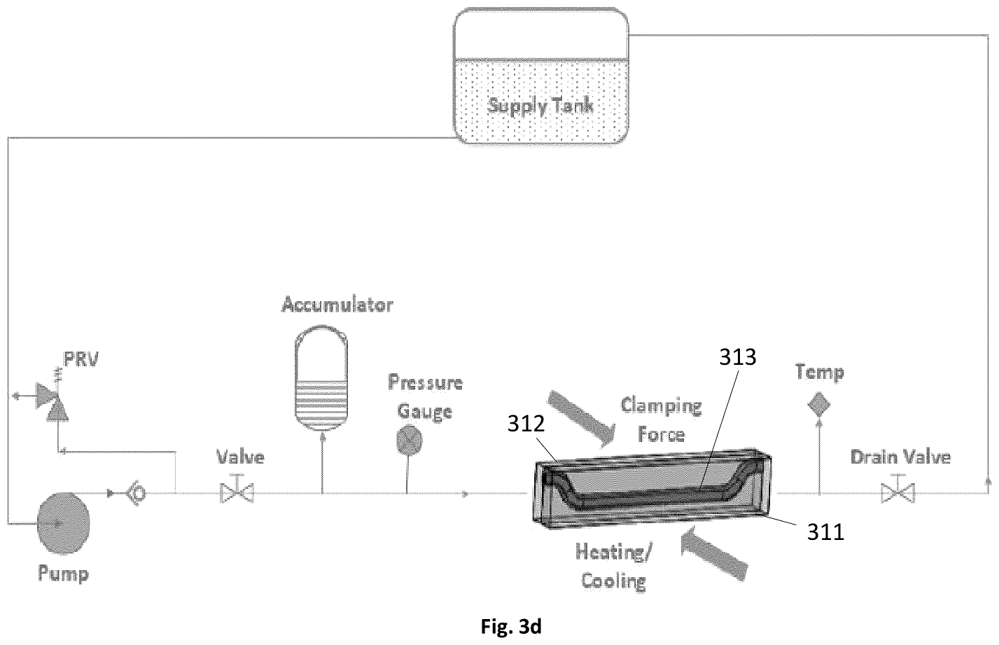

FIGS. 3a through 3d depict a method of manufacturing the above described heat pipe 206 with attached thermally conductive plates 207. As observed in FIG. 3a, a bottom die 301 has a cavity 302 whose floor 303 is shaped with the desired form for a base 304 from which two thermally conductive plates will emanate. Here, the base's bottom surface should fit over the contour of the heat pipe 206 where the base 304 is to attach to the heat pipe 206. As observed in FIG. 3a a piece of sheet metal 305 is placed over the cavity 302 of the bottom die 301. Then, a top die 306 that is formed to fit within the cavity 302 is positioned above the cavity 302 (FIG. 3a) and then pressed into the cavity (FIG. 3b), e.g., with a hydraulic or mechanical press.

The forceful pressing of the top die 306 into the bottom die 301 effectively stamps the sheet metal 305 into the desired shape. As can be seen in FIG. 3b, the shape includes the bottom base 304 that is to be brazed to the heat pipe and two “fins” 307_1, 307_2 that emanate from the base 304 which correspond to a pair of thermally conductive plates that are to be placed in thermal contact with facing sides of different, neighboring DIMMs. Essentially, the sheet metal 305 is bent to form both thermally conductive plates 307_1, 307_2 and a base 304 from the single metal sheet 305.

The process of FIGS. 3a and 3b is repeated to create a second pair of thermally conductive plates and corresponding base.

FIGS. 3c and 3d depict a process for forming the heat pipe 206. As observed in FIG. 3c, a metal pipe 313 is bent to coarsely fit into the respective cavities of a left die 311 and a right die 312. The left and right die 311, 312 are then forcefully pressed together (e.g., with a hydraulic or mechanical press or vice). The forceful pressing together of the left and right die 311, 312 causes the metal pipe 313 to further conform to the contours of the cavity that exists within space between the left and right die 311, 312. The conformance corresponds to a shape that the aforementioned thermally conductive plate base is to fit to.

Then, as observed in FIG. 3d, in order to ensure that the aforementioned bending/conforming of the metal pipe 313 has not crimped or otherwise narrowed its internal, hollow space in a manner that would restrict fluid flow, oil or other liquid having some mass is forcefully driven through the pipe 313 (FIG. 3d depicts the apparatus to force the liquid through the pipe). The forceful driving of the liquid through the pipe 313 causes the pipe 313 to expand against the walls of the cavity within the die 311, 312 thereby “blowing out” any crimp or other internal formation of the pipe that restricts fluid flow.

After the pipe and thermally conductive plates have been formed, both pairs of thermally conductive plates are brazed to the pipe at their base in the correct location.

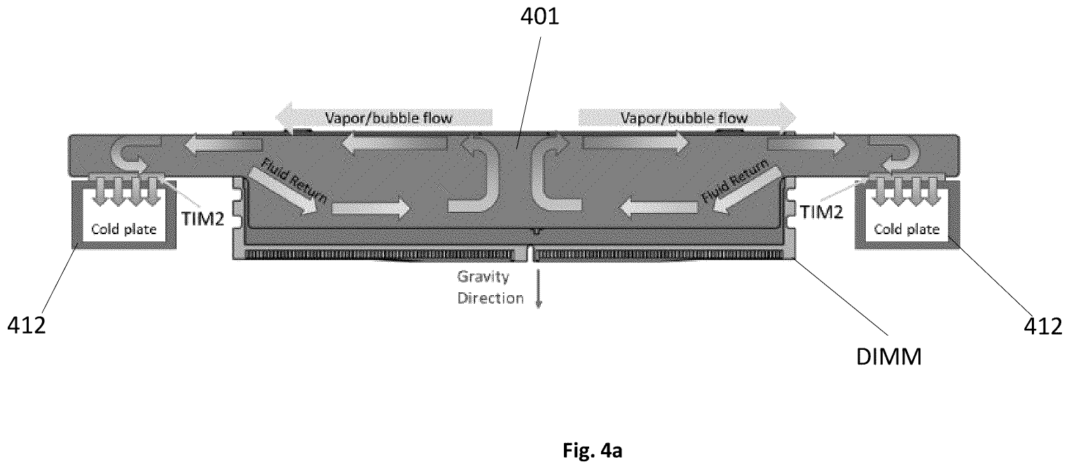

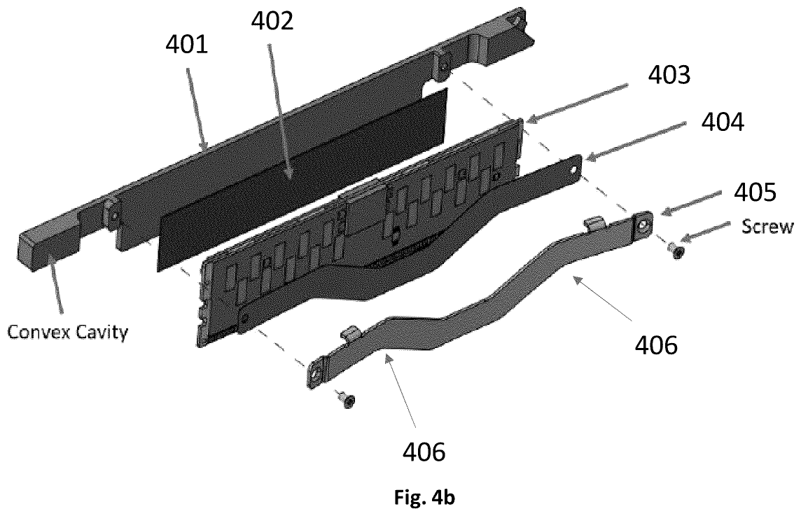

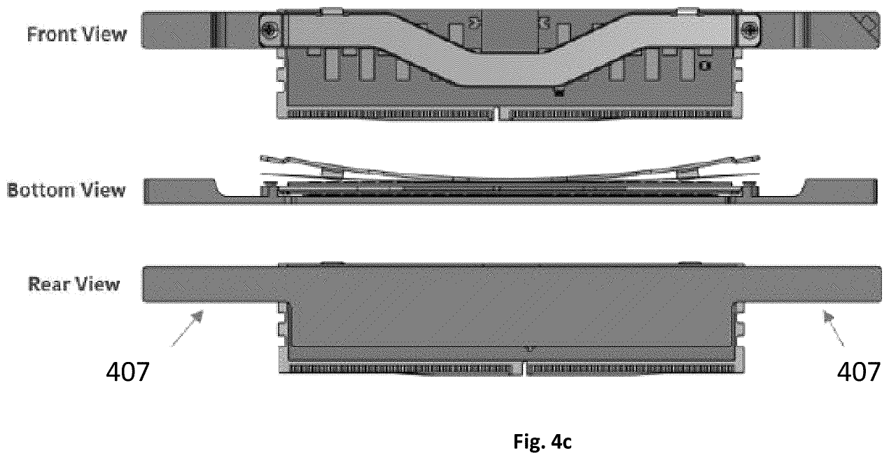

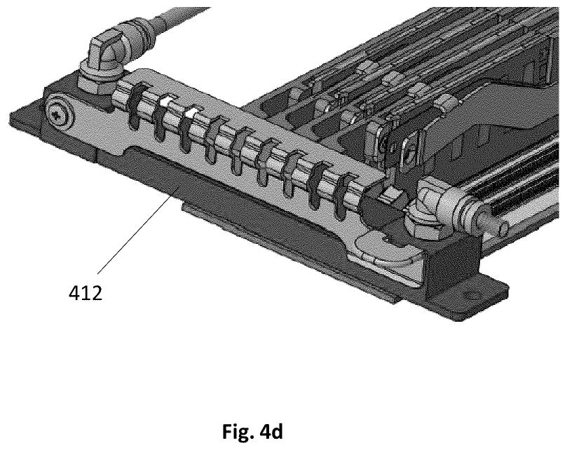

FIG. 4a through FIG. 4d pertain to another cooling assembly embodiment. FIG. 4a shows another DIMM cooling assembly in which a self contained vapor chamber 401 is placed across the chips of a DIMM face. A self contained vapor chamber 401 includes a pool of liquid at the bottom of a sealed chamber. As the chamber receives heat from the DIMM's semiconductor chips, the liquid in the chamber boils thereby transferring the absorbed heat from the liquid into the vapor.

The upper region of the chamber is in thermal contact with a pair of cold plates 412 at each end of the chamber 401. The cold plates 412 are structurally similar to the manifolds 107, 108 discussed above with the exception that the cold plates 412 do not run fluid through the chamber 401. Rather, the chamber 401 simply makes mechanical contact to the cold plates 412 without any fluid being passes through the chamber/plate interface.

The vapor impinges upon the upper region of the chamber 401 which transfers the heat from the vapor to the upper region of the chamber 401 and then from the upper region of the chamber 401 to cold plates 412. The removal of the heat from the vapor condenses the vapor back to a liquid which falls into the pool at the bottom of the chamber 401. Liquid runs through the cold plates 412. The liquid absorbs the heat that is transferred to the cold plates 412 from the chamber 401 while it is running through the cold plates 412. The liquid is then cooled and returned to the cold plates 412.

The cooling assembly, as depicted in FIG. 4b, includes the vapor chamber 401 and a first thermal interface material 402. The first thermal interface material 402 is sandwiched between the vapor chamber 401 and the semiconductor chips that are disposed on a first face of the DIMM 403 to help transfer heat generated by the chips to the surface of the vapor chamber 401.

An electrically insulating material 404 is sandwiched between the chips that are disposed on the other face of the DIMM 403 and a leaf spring 405. The electrically insulating material 404 electrically isolates the leaf spring 405 (which is composed of metal or other rigid material such as hard plastic) from the other face of the DIMM 403 and its chips/devices. In order to mechanically integrate the elements 401-405 of the assembly together, screws, bolts or other type of fastening mechanisms run from the leaf spring 405 through the insulating material 404, DIMM card 403 and thermal interface 402 and are secured at standoffs that emanate from surface of the vapor chamber 401. The tightening of the fastening mechanisms bends the leaf spring 405. The bending of the leaf spring 405 drives the knees 406 of the leaf spring toward the vapor chamber 401 which compresses the assembly elements tightly together. FIG. 4c shows multiple views of the completed assembly.

FIG. 4d depicts the insertion of multiples DIMMs having the aforementioned cooling assembly into respective DIMM sockets. For illustrative ease only one end of the DIMMs are shown. As described above, a cold plate 412 runs along the ends of the set of neighboring DIMM sockets. The cold plate 412 has an internal fluidic conduit. The fluidic conduit receives cooled fluid. As the fluid runs through the conduit the fluid absorbs heat that is transferred to the cold plate 412 from the DIMMs' respective vapor chambers. The warmed fluid then exits the conduit to be cooled and then returned back to the cold plate 412 as cooled fluid. In various embodiments, another cold plate also exists on the opposite ends of the DIMMs (not shown in FIG. 4d).

With respect to the transfer of heat from a DIMM's vapor chamber to the cold plates, referring back to FIG. 4c, the vapor chamber has convex “wing” structures 407 that are placed in thermal contact with the cold plates. As the vapor chamber 401 absorbs heat from the vapor inside the chamber, the heat reaches the wings 407. The heat is then transferred from the wings 407 to the cold plates 412. The wings 407 have a larger width than the vapor chamber to increase the surface area on the underside of the wings 407 that are in thermal contact with or are otherwise thermally coupled to the cold plate (thereby decreasing the thermal resistance associated with the transfer of heat from the vapor chamber to the cold plate). The wings 407 can be hollow or be mass blocks.

In various embodiments, referring back to FIG. 4b, the electrical insulating material 404 that is placed between the leaf spring 405 and the other face of the DIMM 403 is thermally conductive (e.g., an electrically insulating thermal interface material, e.g., Aluminum Nitride (AlN)).

FIG. 4e pertains to another cooling structure embodiment having an overall cooling assembly structure like that described just above with respect to FIGS. 4a through 4d but where the cooling mechanism is based on heat pipes rather than a vapor chamber. Said another way, the cooling structure of FIG. 4e can replace the vapor chamber 401 of FIGS. 4a through 4d.

A first view (i) of FIG. 4e shows upper and lower heat pipes 454_1, 454_2 embedded within a thermally conductive housing 451. In various embodiments, the thermally conductive housing 451 is metallic (e.g., a metal (e.g., copper or aluminum) or metal alloy (e.g., bronze)). Second and third views (ii) and (iii) depict back and front views, respectively. Here, as observed in view (ii), the back of the housing 452 completely covers the heat pipes 454_1, 454_2. By contrast, as observed in view (iii), the front of the housing 453 mostly covers the heat pipes 454_1, 454_2.

The front of the housing 453 is placed in thermal contact with semiconductor chips on the side of a DIMM that faces the front of the housing 453. Conceivably, in extended embodiments, the back of the housing 452 is placed in thermal contact with chips of another DIMM that the cooling structure is placed between.

In a first embodiment the heat pipes 454_1, 454_2 are air filled (liquid does not run through them). In a second embodiment fluid flows through the heat pipes 454_1, 454_2 (in which case the heat pipes have cooled fluid inputs and warmed fluid outputs). Regardless, the front of the housing 453 receives heat from the DIMM semiconductor chips and transfers the heat to the heat pipes 454_1, 454_2. The heat is then transferred by and/or within the heat pipes 454_1, 454_2 to convex wing structures 457 at the ends of the thermal cooling structure. The wing structures 457 are like those 407 described just above with respect to FIG. 4 and make thermal contact with respective cold plates. In various embodiments the thermal cooling structure has only one wing structure at one end (rather than a pair of wing structures at both ends).

View (iv) shows that the heat pipes can have flat ends or pointed ends or a combination of flat and pointed ends.

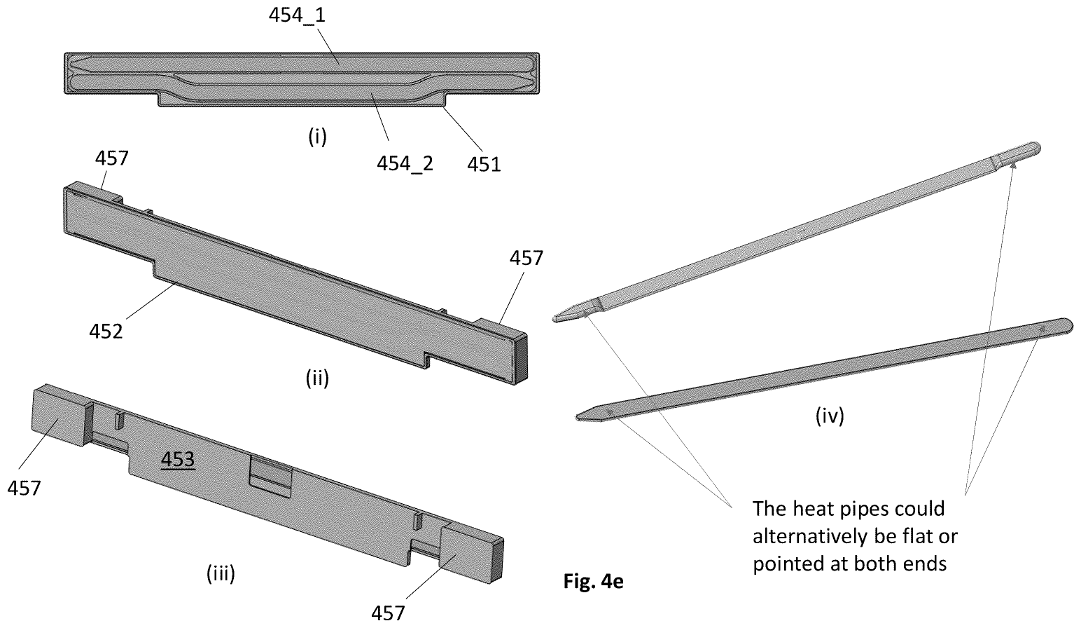

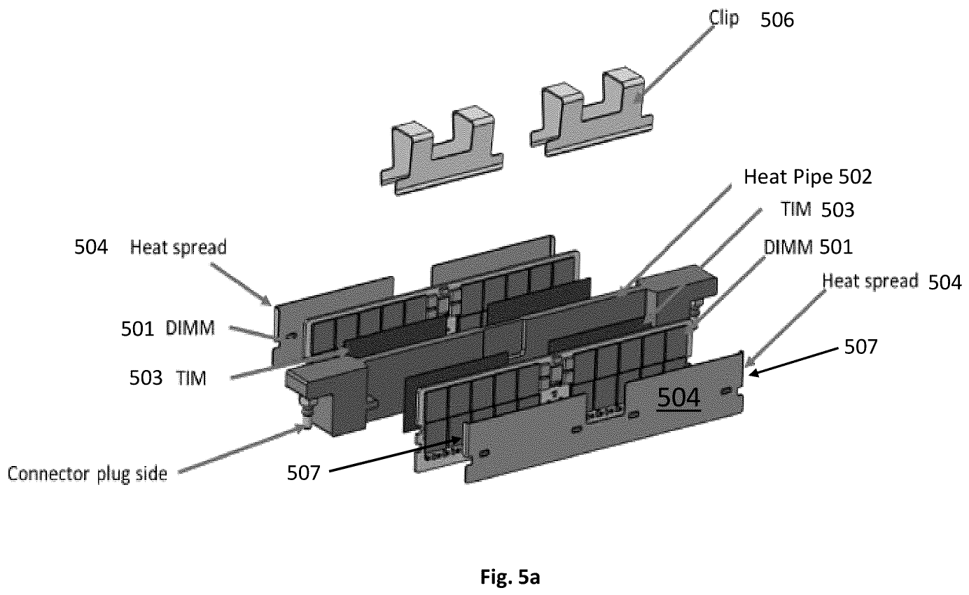

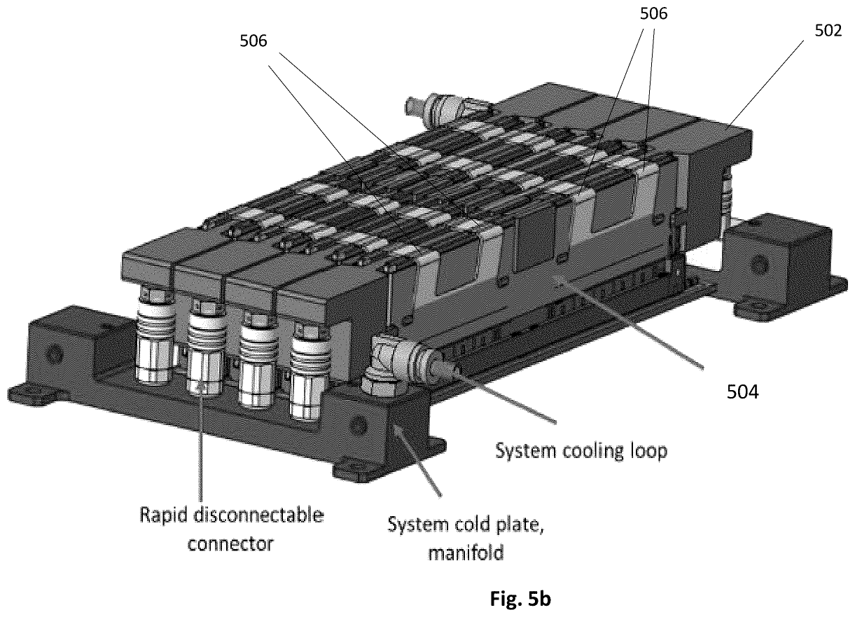

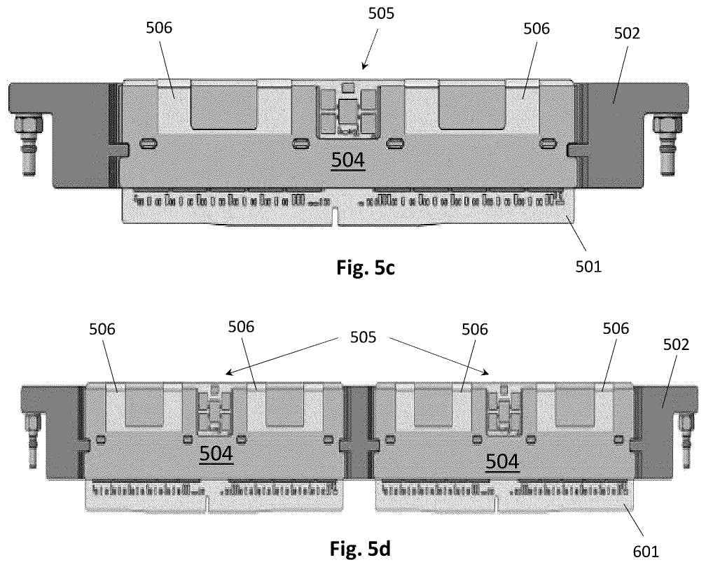

FIGS. 5a through 5d pertain to another cooling assembly in which a pair of neighboring DIMMs are coupled to a same heat pipe or vapor chamber or heat sink that is placed between them. In embodiments where a heat pipe is used, the heat pipe includes a fluidic input on one end and a fluidic output on another end as discussed above with respect to the embodiment of FIGS. 1a through 1f. In embodiments where a vapor chamber is used, the vapor chamber operates as discussed above with respect to the embodiment of FIGS. 4a through 4d. In embodiments where a heat sink is used, the heat sink is a large mass that radiates heat which is carried away by air flow. In this case, liquid is not passed through or vaporized within the heat sink.

For ease of drawing, FIGS. 5a through 5d only depict a heat pipe approach. As such, the remaining discussion only refers to a heat pipe instead of a vapor chamber or heat sink. However, the reader should understand that the cooling assembly described herein can be applied to vapor chamber or heat sink approaches even though only a heat pipe approach is referred to.

As observed in FIGS. 5a through 5d, the cooling assembly places facing sides of neighboring DIMMs 501 in thermal contact with opposite sides of a same heat pipe 502. A respective thermal interface material 503 is sandwiched between each facing DIMM side and the pipe/chamber 502. Heat spreaders 504 are then attached to the outer faces of both DIMMs that are not in direct thermal contact with the pipe/chamber 502. Clips 505 are then placed over the assembly to compress the components together.

FIG. 5a through 5c show an embodiment where there is one heat spreader 504 having one gap 505 and two clips 505 are used to compress the assembly. By contrast, FIG. 5d shows another embodiment where there are two heat spreaders 504 each having one gap 505 and two clips 506. In various embodiments, the heat spreaders 504 are in thermal contact with the DIMM's memory chips, register clock driver chips and buffer chips, whereas, the gap 505 exposes other devices (e.g., capacitors, resistors, etc.) or chips.

The heat spreaders 504 absorb heat from the chips that are disposed on the outer DIMM faces. A number of thermal channels exist between the heat spreaders 505 and the pipe 502 which, in turn, enables heat that is generated by the chips on the DIMMs' outer faces and absorbed by the heat spreaders 504 to be transferred to the plate 502. Here, a first thermal path exists through the clips 506 which are thermally conductive (e.g., composed of metal) and make contact with the heat spreaders 504 and the top surface of the pipe 502. A second thermal path is realized with end tabs 507 that are formed on the heat spreaders 504 and press into the heat pipe 502.

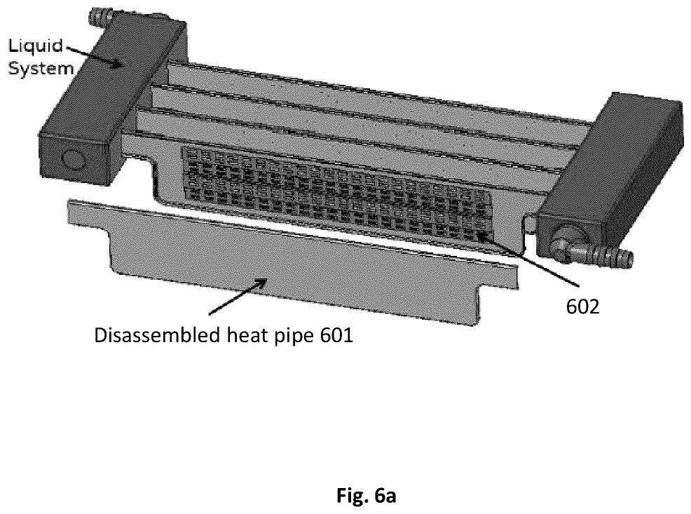

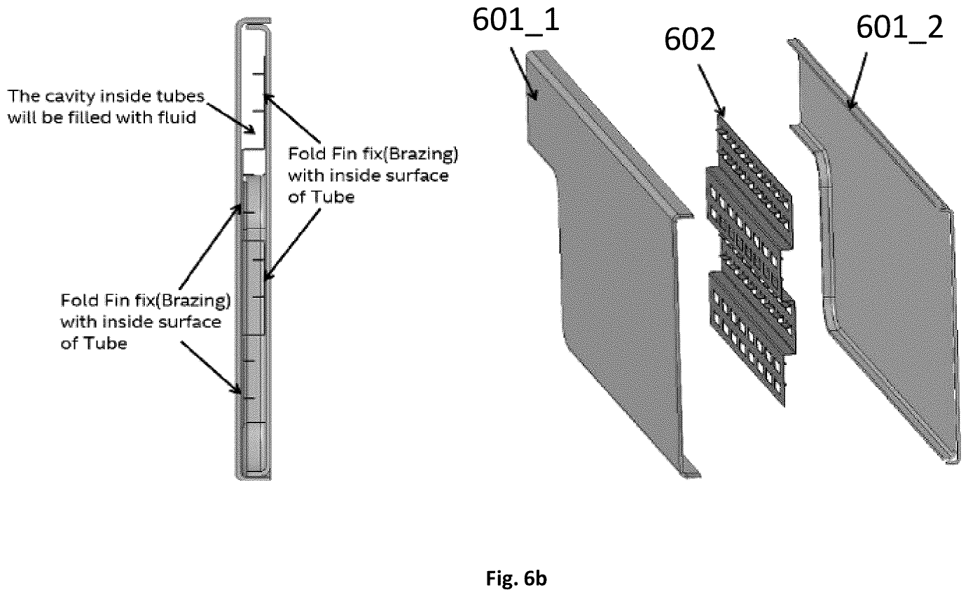

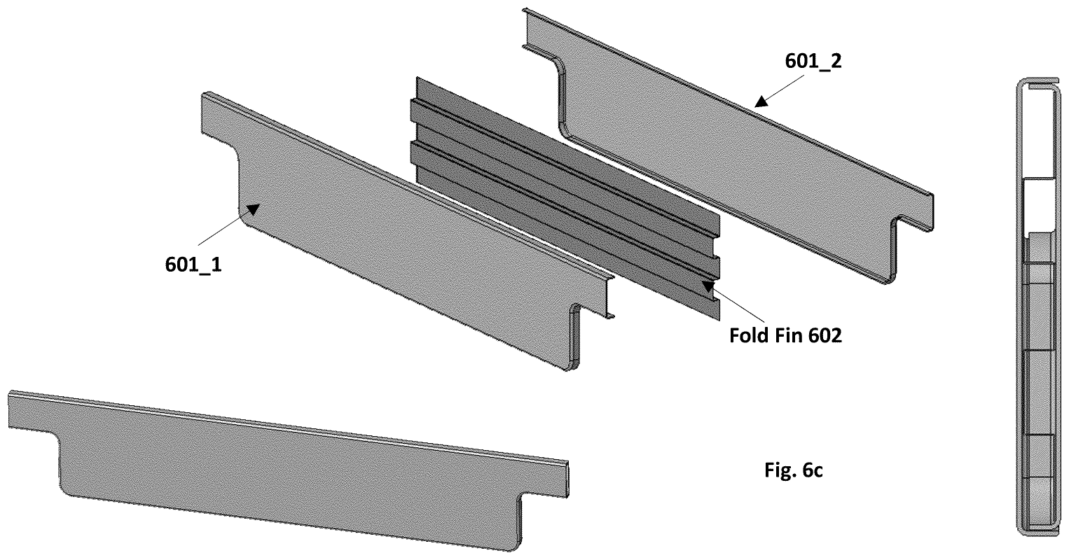

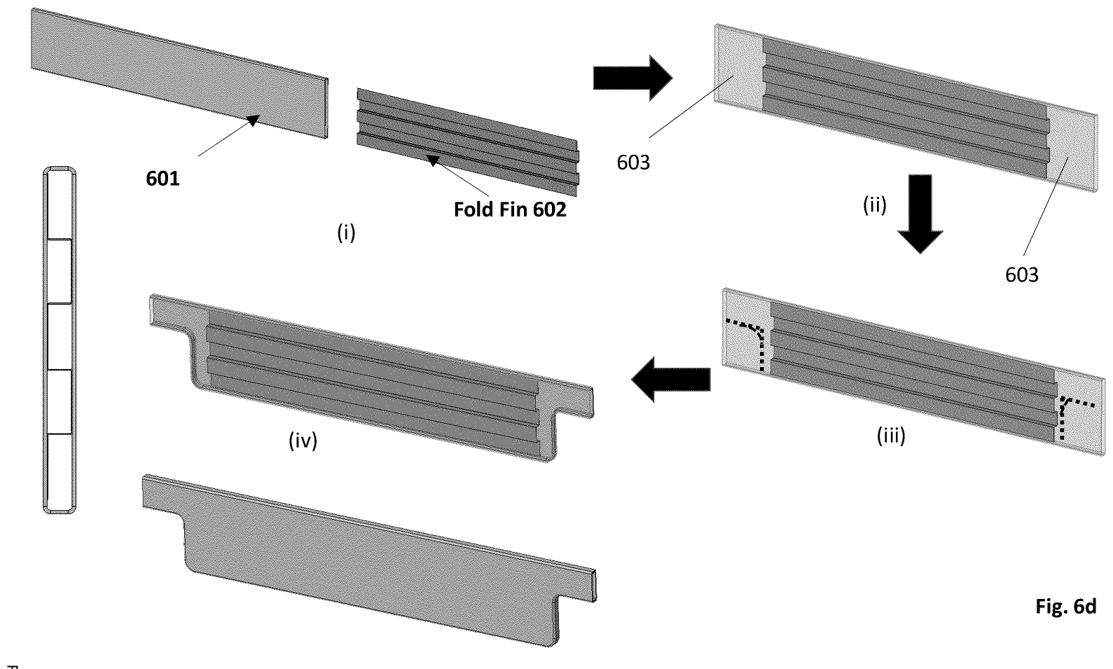

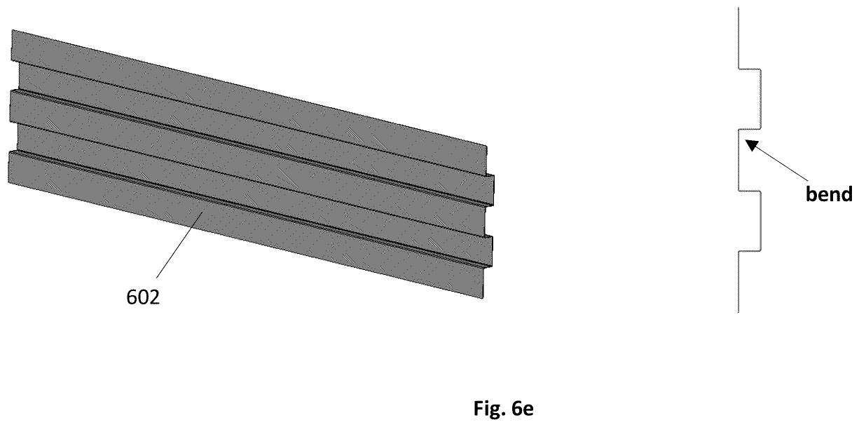

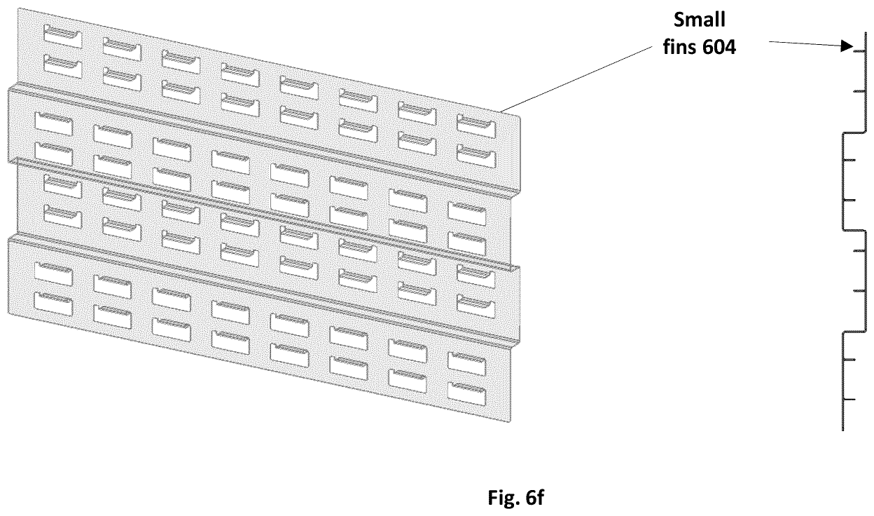

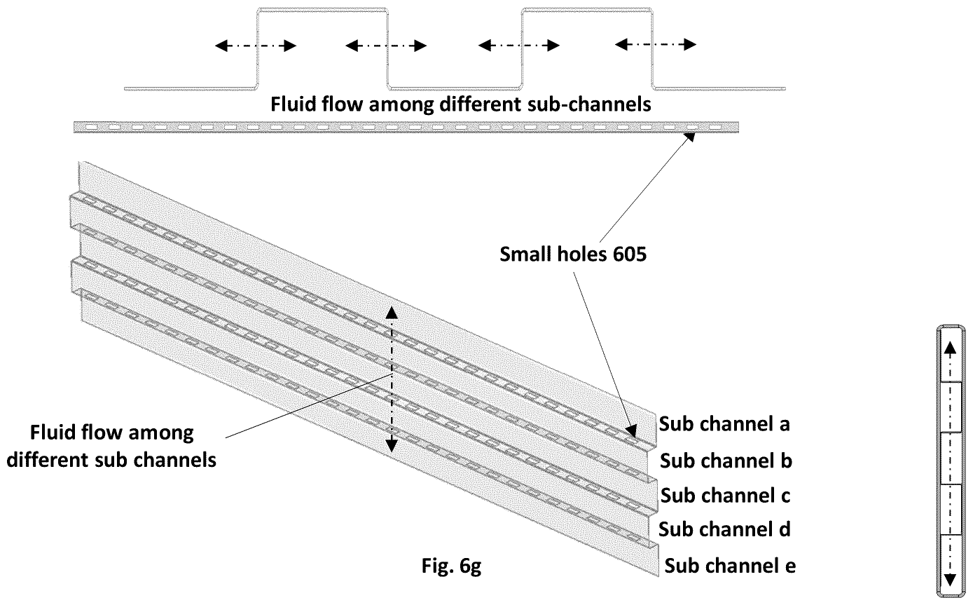

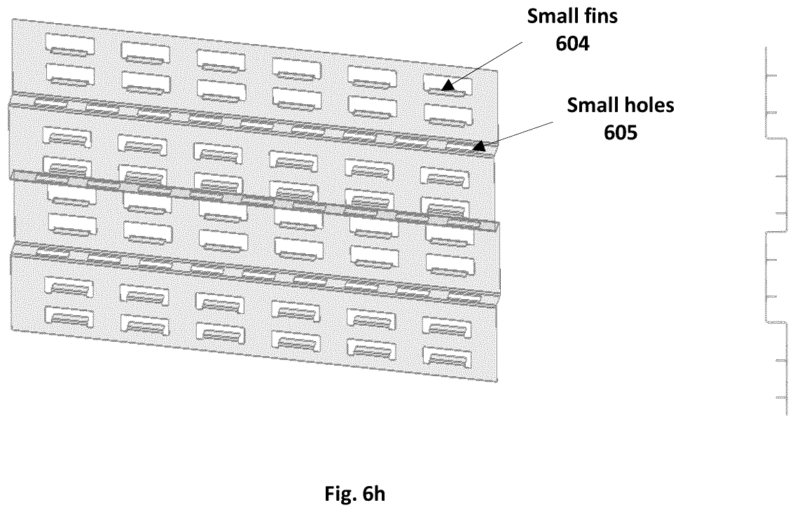

FIGS. 6a through 6h depict improvements that can be applied to any of the heat pipe solutions described above. Here, a heat pipe includes any thermally conductive structure that is hollowed in some way and is used to transfer heat. This includes heat pipes that are air-filled, heat pipes through which fluid flows, vapor chambers, etc.

A heat pipe can have any of a number of different shapes (e.g., a pipe that is rectangular along its length axis having a rectangular cross section). For simplicity, the following discussion is mostly directed to a cooling assembly that uses a rectangular heat pipe through which fluid flows to absorb heat that the heat pipe receives at one or more of its outer surfaces.

FIG. 6a shows an exploded view of a heat pipe 601 that makes thermal contact with the chips on the side of a DIMM (and potentially the chips on the side of a neighboring DIMM). Again, thermal contact means actual contact, or, a thermal resistance that is less than or equal to that achieved with actual contact. The heat pipe 601 can therefore be in thermal contact with the chips on the side of a DIMM if there is thermal interface material between the pipe and chips. Cooled fluid enters the pipe on one end. As the fluid flows through the pipe it absorbs heat from the semiconductor chips. The fluid then exits the pipe as warmed fluid on the opposite end.

A problem is the tight packing density of DIMMs in future systems. In particular, spacing between neighboring DIMMs can be as low as 0.3 inches or less. Such a small spacing narrows the fluidic conduit within the pipe which, in turn, increases the fluidic resistance of the conduit and decreases the thermal transfer efficiency of the pipe (because the conduit contains a reduced flow rate of fluid).

In order to compensate for both the increased fluidic resistance and decreased thermal efficiency, the pressure of the cooled fluid that is injected into the pipe can be increased. Here, the higher pressure overcomes the increased fluidic resistance and translates into faster fluid flow which increases thermal transfer efficiency.

A problem, however, is that the pipe is formed of thin sheet metal or thin metal tubing (e.g., having 0.5 mm thickness or less). Such thin metal is not able to withstand the higher fluidic pressure and will tend to “blow out” like a balloon. Further still, even if the blow-out problem were not existent, the thin metal is not thick enough to withstand compressive forces that the pipe could experience during installation or shipment. Here, for instance, if a face of the pipe receives an inward compressive force (e.g., during its installation or the installation of a nearby DIMM), the internal walls of the conduit will crush inward thereby further narrowing the fluidic channel's cross sectional area if not destroying the fluidic channel outright.

FIG. 6b shows a detailed view of an improved design which incorporates a “fold fin” structure 602. The fold fin structure 602, in various embodiments, is a single piece of metal that is placed between a pair of pipe halves 601_1, 601_2. The pipe halves 601_1, 601_2 are then sealed together (e.g., brazed) forming a pipe with the fold fin structure 602 within the pipe's fluidic conduit.

As can be seen in FIG. 6b, the fold fin structure 602 is: 1) folded/bent to include segments that bridge across the narrow opening of the fluidic channel; 2) have sufficiently large surface areas to attach to both of the fluidic channel's wider inner walls. Both of these properties result in a structure that preservers the mechanical integrity of the pipe. Specifically, 1) above protects against protective forces that would otherwise crush the fluidic channel, whereas, 2) above protects against pipe wall blow-out in response to increased fluidic pressure within the heat pipe's fluidic channel. Additionally, the overall flatness of the pipe surface is improved with the fold fin structure 602 which allows for smaller pipe assembly dimensions.

FIG. 6c shows additional views of the heat pipe of FIG. 6b.

FIG. 6d shows an alternate approach which begins (i) with a fully formed heat pipe 601. A fold fin structure 602 is then inserted (ii) into the heat pipe 601. Notably, there are excess length regions 603 of the heat pipe 602 where the heat pipe 602 extends beyond the fold fin structure 602. The lower corners of the excess length regions 603 are then cut out (iii) and the open edges that result are sealed (e.g., brazed) (iv) to form the far ends of the heat pipe 602 that enclose the fold fin structure 602 within the heat pipe. In various embodiments one of the far ends has a cooled fluid input and the other far end has a warmed fluid output.

FIG. 6e shows an isolated view of a fold fin structure 602. In various embodiments, the design of the fold fin is influenced by the mechanical specifications of the heat pipe and/or the surrounding mechanical assembly. Here, generally, as the spacing between neighboring bends is reduced, the greater the number of bends the structure 602 will have. The greater the number of bends in the structure 602, the more support the fold fin structure 602 provides to the heat pipe 601. Thus, in embodiments where the heat pipe could be subjected to extreme pressures, the fold fin structure is designed to have more bends. Likewise, in embodiments where the heat pipe could be subjected to modest pressures, the fold fin structure is designed to have less bends. Additionally, only a single fold fin structure can exist in a heat pipe, or, multiple fold fin structures can exist in a single heat pipe (e.g., by placing them side by side along the length of the pipe).

FIG. 6f shows a fold fin structure having additional smaller fins 604. The smaller fins 604 can be formed by cutting the surface of the fold fin structure in a particular shape but leaving some portion uncut. The resulting “tab” is then bent to form a smaller fin 604. The smaller fins not only help increase the structural support provided by the fold fin structure (the smaller fins 604 can be viewed as additional bridges that span the fluidic conduit).

The openings in the fold fin structure that result from the formation of the smaller fins 604 increases the thermal efficiency of the heat pipe because they expose the fluid inside the fluidic conduit directly to the outer walls of the heat pipe. Additionally, the smaller fins 604 provide more structural direction to the fluid flow (e.g., circular eddies of fluid flow are less likely).

FIG. 6g shows the addition of small holes 605 along the sidewalls of the fold fin structure. The small holes 605 along the sidewalls allow for “vertical” fluid flow within the heat pipe. Here, without such holes 605, the bends and corresponding sidewalls of the fold fin structure create fluidic “sub-channels” between neighboring sidewalls that can restrict fluid flow leading to decreased thermal transfer efficiency. Allowing for such vertical flows practically eliminates the sub-channels which, in turn, reduces the fluidic resistance and increases thermal transfer efficiency. The small holes can be of varying shapes such as circles, rectangles, triangles, trapezoids, diamonds, etc.

FIG. 6h shows a fold fin structure having both small fins 604 and small holes 605.

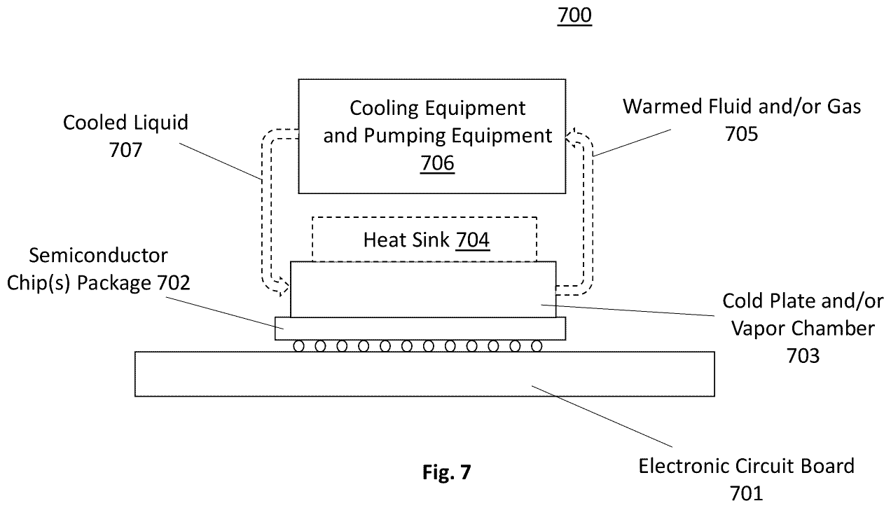

The teachings above can be applied to the cooling apparatus 700 of FIG. 7. FIG. 7 depicts a general cooling apparatus 700 whose features can be found in many different kinds of semiconductor chip cooling systems. As observed in FIG. 7, one or more semiconductor chips within a package 702 (such as memory chips) are mounted to an electronic circuit board 701 (such as a DIMM). A cold plate 703 is thermally coupled with the package 702 (e.g., by being placed on the package 702 with a thermally conductive material (“thermal interface material”) between them) so that the cold plate 703 receives heat generated by the one or more semiconductor chips (the cold plate 703 can also be referred to as a vapor chamber in the case of two phase cooling systems).

Liquid coolant is within the cold plate 703. Notably, the heat pipes discussed above are more generally cold plates. If the system also employs air cooling (optional), a heat sink 704 can be thermally coupled to the cold plate 703. Warmed liquid coolant and/or vapor 705 leaves the cold plate 703 to be cooled by one or more items of cooling equipment (e.g., heat exchanger(s), radiator(s), condenser(s), refrigeration unit(s), etc.) and pumped by one or more items of pumping equipment (e.g., dynamic (e.g., centrifugal), positive displacement (e.g., rotary, reciprocating, etc.)) 706. Cooled liquid 707 then enters the cold plate 703 and the process repeats.

With respect to the cooling equipment and pumping equipment 706, cooling activity can precede pumping activity, pumping activity can precede cooling activity, or multiple stages of one or both of pumping and cooling can be intermixed (e.g., in order of flow: a first cooling stage, a first pumping stage, a second cooling stage, a second pumping stage, etc.) and/or other combinations of cooling activity and pumping activity can take place.

Moreover, the intake of any equipment of the cooling equipment and pumping equipment 706 can be supplied by the cold plate of one semiconductor chip package or the respective cold plate(s) of multiple semiconductor chip packages.

In the case of the later (intake received from cold plate(s) of multiple semiconductor chip packages), the semiconductor chip packages can be components on a same electronic circuit board or multiple electronic circuit boards. In the case of the later (multiple electronic circuit boards), the multiple electronic circuit boards can be components of a same electronic system (e.g., different boards in a same server computer) or different electronic systems (e.g., electronic circuit boards from different server computers). In essence, the general depiction of FIG. 7 describes compact cooling systems (e.g., a cooling system contained within a single electronic system), expansive cooling systems (e.g., cooling systems that cool the components of any of a rack, multiple racks, a data center, etc.) and cooling systems in between.

Although FIG. 7 shows the cold plate 703 in direct contact with a semiconductor chip package, in other embodiments one or more intervening structure(s) can exist along the thermal path between the cold plate and the semiconductor chip package. An example is the vapor chamber approach of FIGS. 4a through 4d in which a vapor chamber 401 is in direct contact with the chips on the DIMM such that the vapor chamber 401 in between the chips on the DIMM and the cold plate 412.

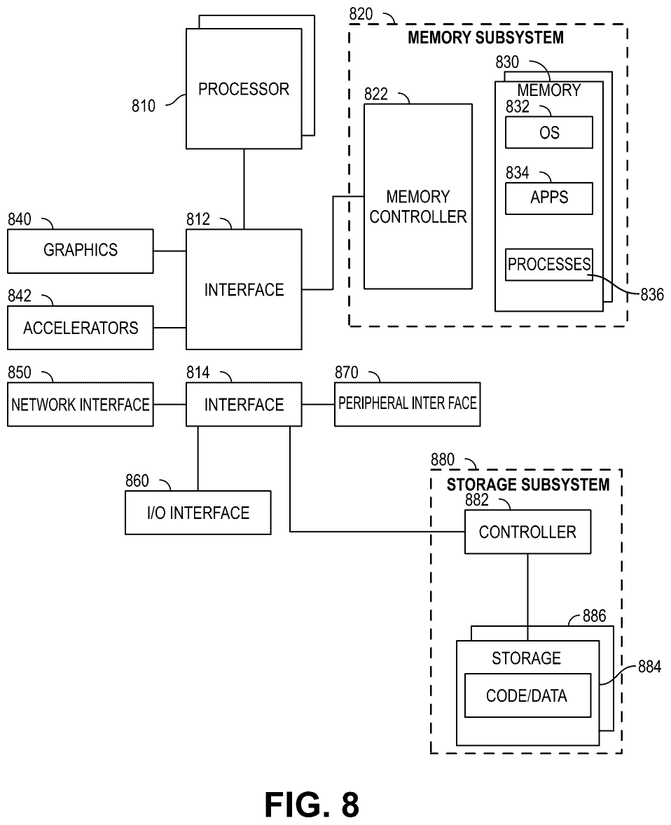

The following discussion concerning FIGS. 8, 9 and 10 are directed to systems, data centers and rack implementations, generally. It is pertinent to point out that any DIMMs of any of the systems, data centers and rack implementations described below can include any of the cooling approaches described above. Such DIMMs can be populated with volatile (e.g., DRAM) memory, non-volatile memory (e.g., flash memory, three-dimensional crosspoint memory) or a combination of both.

FIG. 8 depicts an example system. System 800 includes processor 810, which provides processing, operation management, and execution of instructions for system 800. Processor 810 can include any type of microprocessor, central processing unit (CPU), graphics processing unit (GPU), processing core, or other processing hardware to provide processing for system 800, or a combination of processors. Processor 810 controls the overall operation of system 800, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include one or more network processors to perform such networking functions (e.g., in a pipelined fashion or otherwise).

In one example, system 800 includes interface 812 coupled to processor 810, which can represent a higher speed interface or a high throughput interface for system components that needs higher bandwidth connections, such as memory subsystem 820 or graphics interface components 840, or accelerators 842. Interface 812 represents an interface circuit, which can be a standalone component or integrated onto a processor die. Where present, graphics interface 840 interfaces to graphics components for providing a visual display to a user of system 800. In one example, graphics interface 840 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 840 generates a display based on data stored in memory 830 or based on operations executed by processor 810 or both. In one example, graphics interface 840 generates a display based on data stored in memory 830 or based on operations executed by processor 810 or both.

Accelerators 842 can be a fixed function offload engine that can be accessed or used by a processor 810. For example, an accelerator among accelerators 842 can provide compression (DC) capability, cryptography services such as public key encryption (PKE), cipher, hash/authentication capabilities, decryption, or other capabilities or services. In some embodiments, in addition or alternatively, an accelerator among accelerators 842 provides field select controller capabilities as described herein. In some cases, accelerators 842 can be integrated into a CPU socket (e.g., a connector to a motherboard or circuit board that includes a CPU and provides an electrical interface with the CPU). For example, accelerators 842 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic circuitry, and programmable processing elements such as field programmable gate arrays (FPGAs). Accelerators 842 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 820 represents the main memory of system 800 and provides storage for code to be executed by processor 810, or data values to be used in executing a routine. Memory subsystem 820 can include one or more memory devices 830 such as read-only memory (ROM), flash memory, volatile memory, or a combination of such devices. Memory 830 stores and hosts, among other things, operating system (OS) 832 to provide a software platform for execution of instructions in system 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software functionality to provide functions for system 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810. In some examples, a system on chip (SOC or SoC) combines into one SoC package one or more of: processors, graphics, memory, memory controller, and Input/Output (I/O) control logic circuitry.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

The memory resources can also be tiered (different access times are attributed to different regions of memory), disaggregated (memory is a separate (e.g., rack pluggable) unit that is accessible to separate (e.g., rack pluggable) CPU units), remote (e.g., memory is accessible over a network), and/or pooled (memory can be allocated to the CPUs of multiple computer systems or multiple rack pluggable CPU units).

While not specifically illustrated, it will be understood that system 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (ISCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 800 includes interface 814, which can be coupled to interface 812. In one example, interface 814 represents an interface circuit, which can include standalone components and integrated circuitry. In one example, multiple user interface components or peripheral components, or both, couple to interface 814. Network interface 850 provides system 800 the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can transmit data to a remote device, which can include sending data stored in memory. Network interface 850 can receive data from a remote device, which can include storing received data into memory. Various embodiments can be used in connection with network interface 850, processor 810, and memory subsystem 820.

In one example, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include any hardware interface not specifically mentioned above. Peripherals refer generally to devices that connect dependently to system 800. A dependent connection is one where system 800 provides the software platform or hardware platform or both on which operation executes, and with which a user interacts.

In one example, system 800 includes storage subsystem 880 to store data in a nonvolatile manner. In one example, in certain system implementations, at least certain components of storage 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage 884 holds code or instructions and data in a persistent state (e.g., the value is retained despite interruption of power to system 800). Storage 884 can be generically considered to be a “memory,” although memory 830 is typically the executing or operating memory to provide instructions to processor 810. Whereas storage 884 is nonvolatile, memory 830 can include volatile memory (e.g., the value or state of the data is indeterminate if power is interrupted to system 800). In one example, storage subsystem 880 includes controller 882 to interface with storage 884. In one example controller 882 is a physical part of interface 814 or processor 810 or can include circuits in both processor 810 and interface 814.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 800. More specifically, power source typically interfaces to one or multiple power supplies in system 800 to provide power to the components of system 800. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 800 can be implemented as a disaggregated computing system. For example, the system 800 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Although a computer is largely described by the above discussion of FIG. 8, other types of systems to which the above described invention can be applied and are also partially or wholly described by FIG. 8 are communication systems such as routers, switches and base stations.

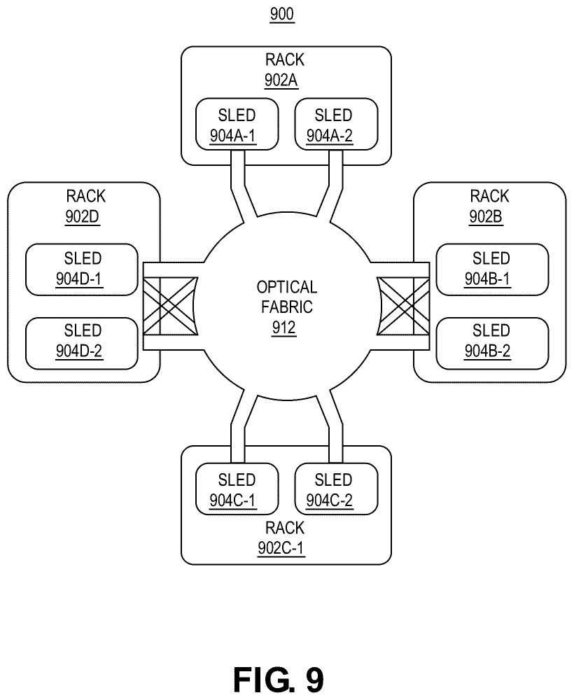

FIG. 9 depicts an example of a data center. Various embodiments can be used in or with the data center of FIG. 9. As shown in FIG. 9, data center 900 may include an optical fabric 912. Optical fabric 912 may generally include a combination of optical signaling media (such as optical cabling) and optical switching infrastructure via which any particular sled in data center 900 can send signals to (and receive signals from) the other sleds in data center 900. However, optical, wireless, and/or electrical signals can be transmitted using fabric 912. The signaling connectivity that optical fabric 912 provides to any given sled may include connectivity both to other sleds in a same rack and sleds in other racks.

Data center 900 includes four racks 902A to 902D and racks 902A to 902D house respective pairs of sleds 904A-1 and 904A-2, 904B-1 and 904B-2, 904C-1 and 904C-2, and 904D-1 and 904D-2. Thus, in this example, data center 900 includes a total of eight sleds. Optical fabric 912 can provide sled signaling connectivity with one or more of the seven other sleds. For example, via optical fabric 912, sled 904A-1 in rack 902A may possess signaling connectivity with sled 904A-2 in rack 902A, as well as the six other sleds 904B-1, 904B-2, 904C-1, 904C-2, 904D-1, and 904D-2 that are distributed among the other racks 902B, 902C, and 902D of data center 900. The embodiments are not limited to this example. For example, fabric 912 can provide optical and/or electrical signaling.

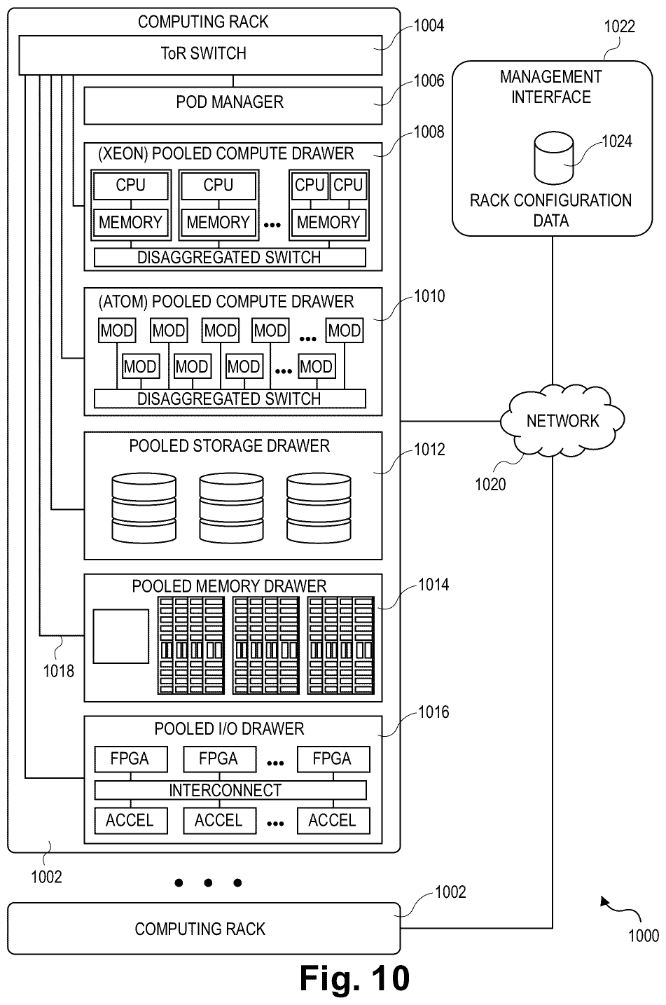

FIG. 10 depicts an environment 1000 that includes multiple computing racks 1002, each including a Top of Rack (ToR) switch 1004, a pod manager 1006, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 1008, and INTEL® ATOM™ pooled compute drawer 1010, a pooled storage drawer 1012, a pooled memory drawer 1014, and a pooled I/O drawer 1016. Each of the pooled system drawers is connected to TOR switch 1004 via a high-speed link 1018, such as a 40 Gigabit/second (Gb/s) or 100 Gb/s Ethernet link or an 100+Gb/s Silicon Photonics (SiPh) optical link. In one embodiment high-speed link 1018 comprises an 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 1000 may be interconnected via their TOR switches 1004 (e.g., to a pod-level switch or data center switch), as illustrated by connections to a network 1020. In some embodiments, groups of computing racks 1002 are managed as separate pods via pod manager(s) 1006. In one embodiment, a single pod manager is used to manage all of the racks in the pod. Alternatively, distributed pod managers may be used for pod management operations. RSD environment 1000 further includes a management interface 1022 that is used to manage various aspects of the RSD environment. This includes managing rack configuration, with corresponding parameters stored as rack configuration data 1024.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store program code. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the program code implements various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof. 5

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

The status of the claims:

1. A system comprising:
a dual in line memory module (DIMM) including a face and memory chips disposed on the face; and
a heat pipe, the heat pipe to be in thermal contact with the memory chips, the heat pipe to receive cooled fluid and emit warmed fluid, the cooled fluid to be converted to the warmed fluid through absorption of heat generated by the memory chips, the heat pipe including a flexible material that presses into the face of the DIMM in response to pressure applied by the received cooled fluid.

2. The system of claim 1, wherein the DIMM is a first DIMM, the face is a first face, the first DIMM plugged into a first socket, and wherein the heat pipe is disposed between the first face of the first DIMM and a second face of a second DIMM, the second DIMM is plugged into a second socket, the second socket adjacent the first socket.

3. The system of claim 2, further including a clip, wherein the first DIMM, the second DIMM, and the heat pipe are coupled via the clip, the clip extending from the first DIMM to the second DIMM.

4. The system of claim 3, wherein the clip is a first clip and further including a second clip, the first DIMM, the second DIMM, and the heat pipe further coupled via the second clip, the second clip extending from the first DIMM to the second DIMM.

5. The system of claim 1, wherein the heat pipe further includes a metal surface disposed therein, the metal surface including a first bend and a second bend, the first bend spaced apart from the second bend.

6. The system of claim 1, further including a frame, wherein the heat pipe is carried by the frame, the frame defined by a hard material extending along a peripheral edge of the heat pipe.

7. The system of claim 6, wherein the heat pipe further includes a tube composed of the flexible material.

8. An apparatus, comprising:
a heat pipe, the heat pipe to be in thermal contact with first memory chips of a dual in line memory module (DIMM), the heat pipe to receive cooled fluid and emit warmed fluid, the cooled fluid converted to the warmed fluid through absorption of heat generated by the first memory chips; and
a thermally conductive plate extending from the heat pipe, the thermally conductive plate to be in thermal contact with second memory chips of the DIMM.

9. The apparatus of claim 8, wherein the DIMM is a first DIMM, the first DIMM plugged into a first socket, and wherein the heat pipe is disposed between the first DIMM and a second DIMM, the second DIMM plugged into a second socket, the second socket adjacent the first socket.

10. The apparatus of claim 9, further including a clip, wherein the first DIMM, the second DIMM, and the heat pipe are coupled via the clip, the clip extending from the first DIMM to the second DIMM.

11. The apparatus of claim 10, wherein the clip is a first clip and further including a second clip, the first DIMM, the second DIMM, and the heat pipe further coupled via the second clip, the second clip extending from the first DIMM to the second DIMM.

12. The apparatus of claim 8, wherein the heat pipe further includes a metal surface, a first portion of the metal surface positioned at a first angle and a second portion of the metal surface positioned at a second angle different from the first angle, the second portion including an opening for fluid flow.

13. The apparatus of claim 8, wherein the DIMM is plugged into a socket, and the second memory chips are farther away from the socket than the first memory chips.

14. The apparatus of claim 8, wherein the thermally conductive plate is a first thermally conductive plate, and the second memory chips are first ones of the second memory chips, and further including a second thermally conductive plate extending from the heat pipe, the second thermally conductive plate to be in thermal contact with second ones of the second memory chips, the second ones of the second memory chips disposed along a same horizontal portion of the DIMM as the first ones of the second memory chips.

15. The apparatus of claim 8, wherein the DIMM is a first DIMM, the first DIMM plugged into a first socket, and the thermally conductive plate is a first thermally conductive plate, and further including a second thermally conductive plate extending from the heat pipe, the second thermally conductive plate to be in thermal contact with third memory chips that are disposed on a second DIMM, the second DIMM plugged into a second socket, the second socket adjacent the first socket.

16. A system comprising:
a cold plate; and
a thermally conductive cooling structure, the thermally conductive cooling structure to be in thermal contact with first memory chips disposed on a face of a dual in line memory module (DIMM), the thermally conductive cooling structure having a wing positioned at an end of the thermally conductive cooling structure, the wing extending beyond an end of the DIMM, the wing being wider along an axis that is perpendicular to the face of the DIMM than a width of the thermally conductive cooling structure within the ends of the DIMM, the wing is to be in thermal contact with the cold plate.

17. The system of claim 16, wherein the thermally conductive cooling structure includes a heat pipe disposed in a thermally conductive housing.

18.-19. (canceled)

20. The system of claim 16, further including a clip to press the DIMM and the thermally conductive cooling structure together.

21. The system of claim 17, wherein the wing is to be in thermal contact with the cold plate.

22. The system of claim 17, wherein the heat pipe includes:
a first surface;
a second surface facing the first surface; and
a third surface positioned between the first surface and the second surface, portions of the third surface extending in a direction from the first surface towards the second surface.
